(19) United States
(12) Patent Application Publication
(10) Pub. No.: US 2026/0321305 A1
(43) Pub. Date: Oct. 15, 2026

(54) OVERWRITING DATA

(71) Applicant: Micron Technology, Inc., Boise, ID (US)

(72) Inventor: Aaron P. BOEHM, Boise, ID (US)

(21) Appl. No.: 19/467,622

(22) Filed: Feb. 2, 2026

Related U.S. Application Data
(60) Provisional application No. 63/781,906, filed on Apr. 1, 2025.

(51) Int. Cl. G11C 11/4078; G11C 11/408; G11C 11/4091; G11C 11/4096

(52) U.S. Cl. CPC G11C 11/4078; G11C 11/4085; G11C 11/4091; G11C 11/4096

(57) ABSTRACT

In some implementations, a memory device may couple, based on performing a read operation, a set of memory cells to a set of sense amplifiers based on applying a first voltage to a word line. The memory device may couple, based on applying a second voltage to a column select line, a subset of memory cells to a set of input/output (I/O) lines as part of the read operation. The memory device may output data from the subset of memory cells to a data bus based on coupling the subset of memory cells to the set of I/O lines. The memory device may drive the set of I/O lines to a third voltage while the subset of memory cells are coupled to the set of I/O lines to overwrite the data output from the subset of memory cells.

### CROSS-REFERENCE TO RELATED APPLICATION

This Patent Application claims priority to U.S. Provisional Patent Application No. 63/781,906, filed on Apr. 1, 2025, entitled “OVERWRITING DATA,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to overwriting data.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source.

### BRIEF DESCRIPTION OF THE DRAWINGS

FIG. 1 is a diagram illustrating an example system capable of overwriting data.

FIG. 2 is a diagrammatic view of an example memory device.

FIG. 3 is a diagram of circuitry that is configured to overwrite data.

FIG. 4 is a timing diagram associated with overwriting data.

FIG. 5 and FIG. 6 are flowcharts of example methods associated with overwriting data.

### DETAILED DESCRIPTION

Some memory devices (e.g., dynamic random access memory (DRAM) devices) may be vulnerable to various exploits that may compromise security and integrity of data stored by the memory devices. For example, a memory device may be targeted by a row hammering attack, where repeated accesses to rows adjacent to a targeted row may induce bit flips of data stored in the targeted row. Therefore, some memory devices employ on-device error correcting codes (ECCs) or targeted refresh schemes that may decrease a likelihood that row hammering attacks induce bit flips. In another example, an attacker may deduce information stored in a targeted row of the memory device by repeatedly accessing rows that are adjacent to the targeted row (e.g., by row hammering the adjacent rows). Such techniques may be exploited to identify data stored in a targeted row even if the targeted row is not accessible to users of a memory device.

Some implementations described herein relate to a memory device that immediately clears data from memory cells after accessing the data stored in the memory cells. As a result, attackers may be less likely to successfully deduce the data stored by the memory cells using row hammering techniques. In particular, during an access operation on the memory cells, the memory device may couple the memory cells to sense amplifiers by applying a voltage to a first word line. To read data from the memory cells, the memory device may couple the memory cells to a set of input/output (I/O) lines by applying a second voltage to a column select line. To clear the data from the memory cells after reading the data from the memory cells, the memory device may drive the I/O lines to a third voltage while the memory cells are still coupled to the set of I/O lines (e.g., while the second voltage is still applied to the column select line), which may overwrite the data output from the memory cells and cause the memory cells to store a uniform value (e.g., corresponding to the third voltage that is applied to the set of I/O lines).

Accordingly, the memory device may clear data stored by the memory cells after accessing (e.g., reading) the data, which may safeguard sensitive information stored by the memory device, such as cryptographic keys. By quickly overwriting the data, the vulnerability window for exploitation through side-channel attacks, such as row hammering adjacent rows, is decreased. Further, clearing the data relatively quickly after accessing the data may improve the integrity and security of the data by deterring unauthorized data retrieval and diminishing the likelihood of bit flips within the data (e.g., resulting from row hammering attacks). In this way, the memory device may conserve processing resources, memory resources, or network resources by reducing the need for additional security measures to combat such attacks and by minimizing the risk of system downtime or breaches that require resource-intensive remediation efforts.

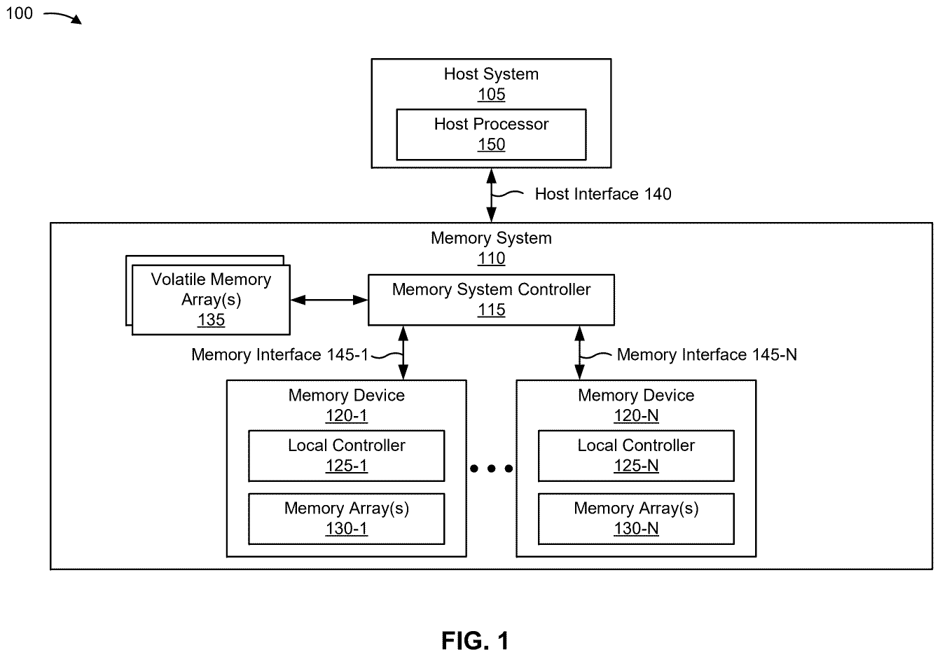

FIG. 1 is a diagram illustrating an example system 100 capable of overwriting data. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N≥1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N≥1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some scenarios, the memory system 110, or a memory device 120 within the memory system 110, may be exposed to attacks that attempt to decrease the security or integrity of data stored within the memory system 110 or the memory device 120. For example, row hammering attacks may correspond to a write side channel attack that operates by repeatedly accessing specific rows in a memory array (e.g., in a volatile memory array 135, such as a DRAM memory array) to induce bit flips in adjacent rows that are physically proximate but inaccessible to the attacker. In some cases, write side channel attacks may correspond to attacks on the memory system 110 that utilize unintended information leakage during write operations to a memory array (e.g., to a volatile memory array 135) within the memory system. The bit flips that are induced by a row hammering attack may result in privilege escalation, which may allow attackers to gain unauthorized access to sensitive information. Some memory systems 110 may employ on-DRAM ECC schemes or targeted refresh schemes to decrease effectiveness of row hammering attacks. In particular, the memory system 110 may use on-DRAM ECC schemes and targeted refresh schemes to detect and correct bit flips or refresh vulnerable rows more frequently, which may improve security and integrity of the data stored by volatile memory arrays 135 within the memory system 110.

In another example, a memory system 110 may be exposed to a read side channel attack, which may leverage row hammering techniques to allow an attacker to deduce the data stored within a row of memory cells even if the row of memory cells is not accessible to a user of the memory device 120 or memory system 110. For example, the volatile memory arrays 135 may include one or more rows of memory cells that are configured to store sensitive information (e.g., cryptographic keys, passwords or authentication tokens, or other confidential information). These rows may be configured to be inaccessible to a user of the memory system 110 (e.g., by the host system 105). However, an attacker may leverage read side channel attacks to deduce the data stored by a row of memory cells.

As an example of a read side channel attack on a volatile memory array 135, an attacker may gain access to a target row of memory cells (e.g., that is not accessible by the host system 105) by row hammering one or more rows of memory cells that are proximal to the target row of memory cells and that are accessible to the host system 105. Then, the attacker may deduce a value of a secret bit (e.g., stored by the target row of memory cells) based on whether a bit in a proximal row of memory cells flips after the row hammering. For example, a memory cell in the proximal row of memory cells contains a flippable bit (e.g., a bit that is flippable by row hammering) that is initially set to a logic value “1.” If the secret bit (e.g., stored by the target row of memory cells) is storing a logic value “0,” the memory cell in the proximal row may not flip after the row hammering. Conversely, if the secret bit is a logic value “1,” the memory cell in the proximal row may flip (e.g., to a logic value “0” after the row hammering). Accordingly, an attacker may infer the value in the target row of memory cells by reading the data stored in the proximal row of memory cells and determining whether the bit stored by the proximal row of memory cells has flipped (e.g., even without directly accessing the data stored by the target row of memory cells).

These read side channel attacks may be dependent upon the target row of memory cells storing the data for an extended period of time (e.g., for more than 64 milliseconds) during which one or more proximal rows of memory cells are row hammered. Some sensitive data, such as cryptographic keys, may be used by the memory system 110 for a brief period. Accordingly, clearing the sensitive data from the volatile memory array 135 immediately after reading the sensitive data may decrease a likelihood of an attacker successfully obtaining the sensitive data using read side channel attacks. That is, the memory system 110 (or a memory device 120 within the memory system that includes a volatile memory array 135) may overwrite data from a set of memory cells (e.g., at a column level) following a read operation of the data. Therefore, the window of opportunity for attackers to exploit read side channel attacks to obtain the data may be reduced, which may enhance the overall security of the memory system 110.

In some implementations, one or more systems, devices, apparatuses, components, and/or controllers of FIG. 1 may be configured to couple, based at least in part on performing a read operation, a set of memory cells to a set of sense amplifiers based at least in part on applying a first voltage to a word line; couple, based at least in part on applying a second voltage to a column select line, a subset of memory cells to a set of I/O lines as part of the read operation; output data from the subset of memory cells to a data bus based at least in part on coupling the subset of memory cells to the set of I/O lines; and drive the set of I/O lines to a third voltage while the subset of memory cells are coupled to the set of I/O lines to overwrite the data output from the subset of memory cells.

In some implementations, one or more systems, devices, apparatuses, components, and/or controllers of FIG. 1 may be configured to activate a word line based at least in part on initiating an execution of a read operation on a set of memory cells that are coupled to the word line; activate, while the word line is activated, a column select line coupled to the set of memory cells; and apply, while the word line and the column select line are activated, a voltage to the set of memory cells to store a uniform value in each memory cell of the set of memory cells.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

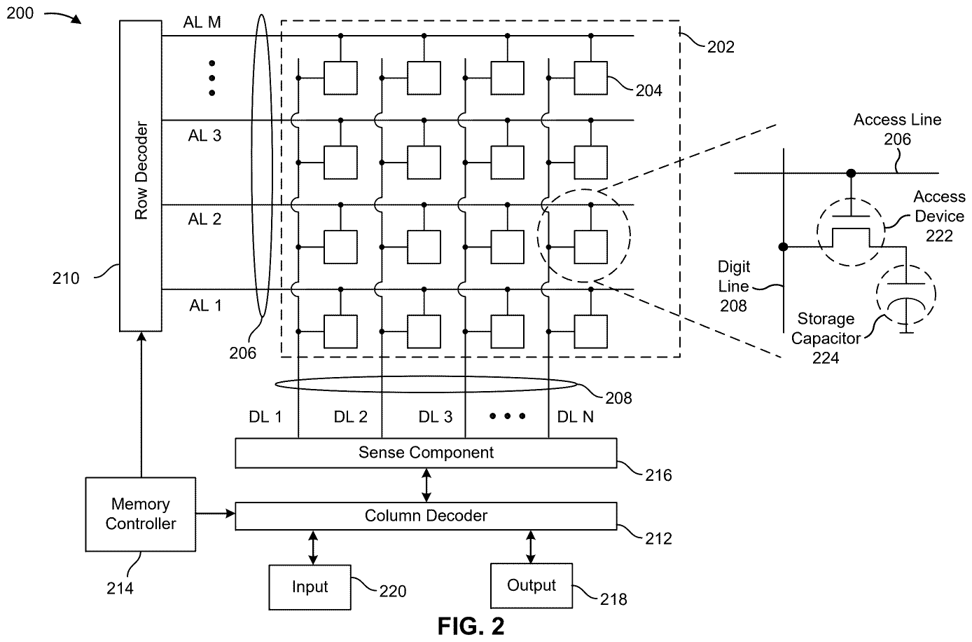

FIG. 2 is a diagrammatic view of an example memory device 200. The memory device 200 may be an example of a memory device 120, as described with reference to FIG. 1. The memory device 200 may include a memory array 202 that includes multiple memory cells 204. In some cases, the memory array 202 may correspond to a DRAM array. A memory cell 204 is programmable or configurable into a data state of multiple data states (e.g., two or more data states). For example, a memory cell 204 may be set to a particular data state at a particular time, and the memory cell 204 may be set to another data state at another time. A data state may correspond to a value stored by the memory cell 204. The value may be a binary value, such as a binary 0 or a binary 1, or may be a fractional value, such as 0.5, 1.5, or the like. A memory cell 204 may include a capacitor to store a charge representative of the data state. For example, a charged and an uncharged capacitor may represent a first data state and a second data state, respectively. As another example, a first level of charge (e.g., fully charged) may represent a first data state, a second level of charge (e.g., fully discharged) may represent a second data state, a third level of charge (e.g., partially charged) may represent a third data state, and so on.

Operations such as reading and writing (e.g., cycling) may be performed on memory cells 204 by activating or selecting the appropriate access line 206 (shown as access lines AL 1 through AL M) and digit line 208 (shown as digit lines DL 1 through DL N). An access line 206 may also be referred to as a “row line” or a “word line,” and a digit line 208 may also be referred to a “column line” or a “bit line.” Activating or selecting an access line 206 or a digit line 208 may include applying a voltage to the respective line. An access line 206 and/or a digit line 208 may comprise, consist of, or consist essentially of a conductive material, such as a metal (e.g., copper, aluminum, gold, titanium, or tungsten) and/or a metal alloy, among other examples. In FIG. 2, each row of memory cells 204 is connected to a single access line 206, and each column of memory cells 204 is connected to a single digit line 208. By activating one access line 206 and one digit line 208 (e.g., applying a voltage to the access line 206 and digit line 208), a single memory cell 204 may be accessed at (e.g., is accessible via) the intersection of the access line 206 and the digit line 208. The intersection of the access line 206 and the digit line 208 may be called an “address” of a memory cell 204.

In some implementations, the logic storing device of a memory cell 204, such as a storage capacitor 224, may be electrically isolated from a corresponding digit line 208 by an access device 222, such as a transistor. The access line 206 may be connected to and may control the access device 222. For example, the access device 222 may be a transistor, and the access line 206 may be connected to the gate of the transistor. Activating the access line 206 results in an electrical connection or closed circuit between the storage capacitor 224 of a memory cell 204 and a corresponding digit line 208. The digit line 208 may then be accessed (e.g., is accessible) to either read from or write to the memory cell 204.

A row decoder 210 and a column decoder 212 may control access to memory cells 204. For example, the row decoder 210 may receive a row address from a memory controller 214 and may activate the appropriate access line 206 based on the received row address. In some cases, activating the appropriate access line 206 may couple the memory cells 204 that are associated with the activated access line 206 to the sense component 216. Similarly, the column decoder 212 may receive a column address from the memory controller 214 and may activate the appropriate digit line 208 based on the column address.

Upon accessing a memory cell 204, the memory cell 204 may be read (e.g., sensed) by a sense component 216 to determine the stored data state of the memory cell 204. For example, after accessing the memory cell 204, the storage capacitor 224 of the memory cell 204 may discharge onto its corresponding digit line 208. Discharging the storage capacitor 224 may be based on biasing, or applying a voltage, to the storage capacitor 224. The discharging may induce a change in the voltage of the digit line 208, which the sense component 216 may compare to a reference voltage (not shown) to determine the stored data state of the memory cell 204. For example, if the digit line 208 has a higher voltage than the reference voltage, then the sense component 216 may determine that the stored data state of the memory cell 204 corresponds to a first value, such as a binary “1.” Conversely, if the digit line 208 has a lower voltage than the reference voltage, then the sense component 216 may determine that the stored data state of the memory cell 204 corresponds to a second value, such as a binary “0.”

The detected data state of the memory cell 204 may then be output (e.g., via the column decoder 212) to an output component 218 (e.g., a data buffer). In particular, the column decoder 212 may include a set of access devices (e.g., such as transistors) that selectively couple the set of digit lines 208 to the output component 218 (e.g., via a set of I/O lines). Accordingly, based on addresses associated with a read operation, the column decoder 212 may couple one or more of the digit lines 208 to the output component 218 in order to output the data from the sense component 216 to the output component 218.

A memory cell 204 may be written (e.g., set) by activating the appropriate access line 206 and digit line 208. The column decoder 212 may receive data, such as input from input component 220, to be written to one or more memory cells 204. A memory cell 204 may be written by applying a voltage across the storage capacitor 224 of the memory cell 204.

The memory controller 214 may control the operation (e.g., read, write, re-write, refresh, and/or recovery) of the memory cells 204 via the row decoder 210, the column decoder 212, and/or the sense component 216. The memory controller 214 may generate row address signals and column address signals to activate the desired access line 206 and digit line 208. The memory controller 214 may also generate and control various voltages used during the operation of the memory array 202.

In some cases, the memory controller 214 may cause the memory device 200 to clear data from a set of memory cells 204 after the data is output from the set of memory cells 204 (e.g., as part of a read operation). Clearing or overwriting the data after outputting the data from the set of memory cells 204 may improve security of the data (e.g., by reducing a likelihood that an attacker can obtain the data via side channel attacks). That is, the set of memory cells 204 may be storing sensitive data, such as cryptographic keys, that is not accessible by a user of the memory device. Accordingly, protecting the data from being accessed may improve reliability and security of the data stored by the memory device 200.

To clear the data after outputting the data from a set of memory cells 204, the memory controller 214 may drive the I/O lines associated with the set of memory cells 204 to a voltage while the set of memory cells 204 are coupled to the I/O lines. In particular, the memory controller 214 may drive the I/O lines (e.g., that couple the output component 218 to the sense component 216) to a uniform voltage while access line 206 is activated, which may in turn overwrite the data stored in the set of memory cells 204 with a uniform value that is based on the uniform voltage applied to the I/O lines. For example, the memory controller 214 may drive the I/O lines to a low voltage, which may cause the set of memory cells 204 to store a logic value “0.” In another example, the memory controller 214 may drive the I/O lines to a high voltage, which may cause the set of memory cells 204 to store a logic value “1.”

As indicated above, FIG. 2 is provided as an example. Other examples may differ from what is described with respect to FIG. 2.

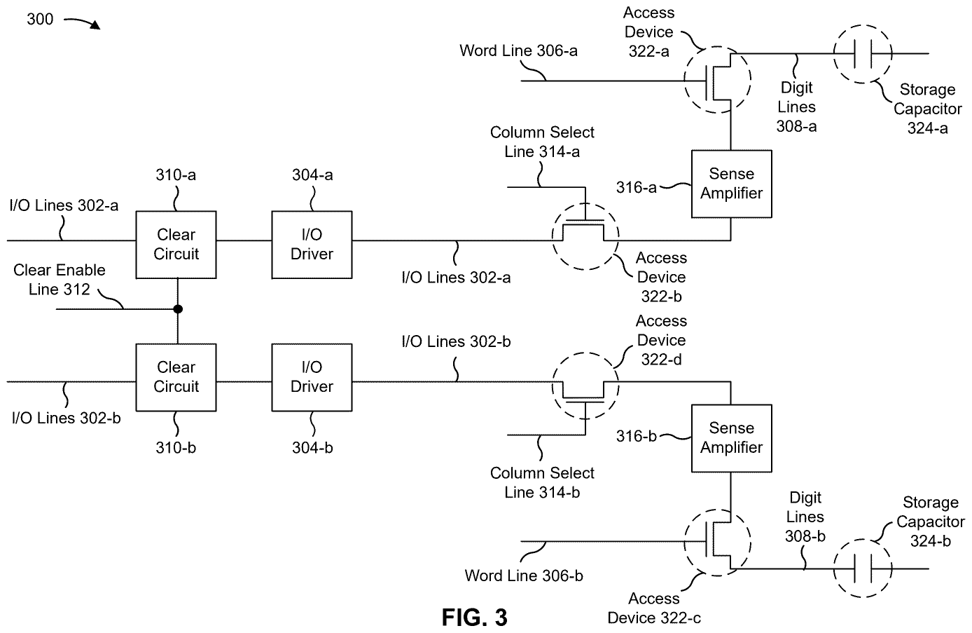

FIG. 3 is a diagram of circuitry 300 that is configured to overwrite data. The memory system 110 or the memory device 200 may include the circuitry 300. Additionally, the circuitry 300 may include aspects of the memory device 200. For example, the circuitry 300 may include word lines 306, which may be examples of the access lines 206; digit lines 308, which may be examples of the digit lines 208; storage capacitors 324, which may correspond to the storage capacitors 224; and access devices 322, which may be examples of the access devices 222. Additionally, one or more components within the memory system 110 or the memory device 200 may include aspects of the circuitry 300. For example, the I/O lines 302 and the I/O driver 304 may be included within the output component 218 and/or the input component 220, the sense amplifiers 316 may be included within the sense component 216, or the column select lines 314 may be included within the column decoder 212.

The circuitry 300 illustrates two example memory cells, corresponding to a first storage capacitor 324-a and a second storage capacitor 324-b. The storage capacitors 324 may be selectively coupled to sense amplifiers 316 via the digit lines 308 and the access devices 322. In particular, the gates of the access device 322-a and the access device 322-c may be coupled to the word line 306-a and the word line 306-b, respectively. If a word line 306 is activated (e.g., turned on, if a high voltage such as V_{CC} is applied to the word lines 306), the access device 322 (which may correspond to a transistor) may turn on and couple the storage capacitor 324 to the sense amplifier 316 by way of the digit line 308.

For example, to access the memory cell associated with the storage capacitor 324-a, a local memory controller (e.g., using a row decoder, as described with reference to FIG. 2) may activate the word line 306-a by applying a voltage to the word line 306-a (e.g., by applying a supply voltage to the word line 306-a, such as V_{CC}). That is, the local memory controller may receive or generate an access command that indicates an address associated with the word line 306-a. The row decoder may decode the address to identify the row or word line associated with the access command (e.g., the word line 306-a). Then, the local memory controller may activate the word line 306 that is associated with the row address indicated by the access command. In this example, the applied voltage to the word line 306-a may activate the access device 322-a, which may cause the storage capacitor 324-a to discharge a charge onto the digit line 308-a toward the sense amplifier 316-a.

If a word line 306 is activated, a charge of the storage capacitor 324 coupled to the activated word line 306 is transferred to a sense amplifier 316 by way of a digit line 308. When the charge of the storage capacitor 324 is transferred to the sense amplifier 316, the sense amplifier 316 may activate. When the sense amplifier 316 activates, the sense amplifier 316 may detect a small voltage difference between the digit line 308 and a complementary digit line (e.g., not illustrated) that is precharged to a reference voltage (e.g., to V_{CC}/2). The sense amplifier 316 may amplify the difference between the voltage of the digit line 308 and the reference voltage, and pull one of the digit line 308 and the complementary digit line to the high rail (Vcc) and the other of the digit line 308 and the complementary digit line to the low rail (e.g., ground), which may stabilize the digit line 308 to represent a binary value stored in the corresponding storage capacitor 324.

The column select line 314 may be configured to selectively couple the sense amplifier 316 to the I/O line 302 and the I/O driver 304. That is, the column select line 314 may be coupled to a gate of an access device 322. In particular, the column select line 314-a may be coupled to the gate of the access device 322-b, and the column select line 314-b may be coupled to the gate of the access device 322-d. If the column select line 314-a is activated (e.g., if a high voltage, such as V_{CC}, is applied to the column select line 314-a), the access device 322-b may be turned on and may couple the sense amplifier 316-a to the I/O lines 302-a and the I/O driver 304-a. Additionally, if the column select line 314-b is activated (e.g., if a high voltage, such as V_{CC}, is applied to the column select line 314-b), the access device 322-d may be turned on and may couple the sense amplifier 316-b to the I/O lines 302-b and the I/O driver 304-b.

An access operation (e.g., a read operation, a write operation) may be associated with a column address (e.g., a set of memory cells that are associated with a column). A column decoder (such as the column decoder 212) may identify the column address associated with the access operation and apply a voltage (e.g., a high voltage, such as V_{CC}) to the column select line 314 that is associated with the identified column address. Accordingly, the sense amplifiers 316 that correspond to the set of memory cells that are associated with the column address may be coupled to the I/O lines 302 and the I/O drivers 304 that are associated with the access operation (e.g., and indicated by the column address). The I/O drivers 304 may be configured to drive data from the digit lines 308 (e.g., and to an output component 218 such as a data buffer) for a read operation or drive data to the digit lines 308 (e.g., and from an input component 220 such as a data buffer) for a write operation.

The address indicated by an access command may indicate both a row address (e.g., associated with a word line 306) and a column address (e.g., associated with a column select line 314). Each word line 306 may be configured to couple a set of memory cells to a corresponding set of sense amplifiers 316, and each column select line 314 may be configured to couple a subset of memory cells from the set to a corresponding quantity of I/O lines. Accordingly, a read operation may be associated with both a row address and a column address, and may result in the memory device outputting data from a subset of the memory cells that are associated with the word line 306 indicated by the row address and the column select line 314 indicated by the column address.

The circuitry 300 may include clear circuits 310. While the clear circuits 310 are illustrated as distinct from the I/O drivers 304, in some cases the clear circuits 310 may be included within the I/O drivers 304. A clear circuit 310 may be configured to drive the I/O lines 302 to a voltage (e.g., to a high voltage such as V_{CC}, to a low voltage such as a ground voltage) to overwrite the data stored in a subset of memory cells after outputting data from the subset of memory cells (e.g., as part of a read operation). In particular, the clear circuit 310 may be coupled to a clear enable line 312. If the clear enable line 312 is high (e.g., is driven to a high voltage, such as V_{CC}), the clear circuit 310 may drive the I/O lines 302 coupled to the clear circuit 310 to a high voltage or a low voltage. The clear enable line 312 may apply a voltage (e.g., a high voltage, such as V_{CC}) to a clear circuit 310 while a column select line 314 is applying a voltage (a high voltage, such as V_{CC}) to an access device 322 and a word line 306 is applying a voltage to an access device 322. Accordingly, the clear enable line 312 may apply the voltage to the clear circuit 310 while at least one of the storage capacitor 324-a or the storage capacitor 324-b is coupled to the I/O lines 302-a or the I/O lines 302-b, respectively. Accordingly, the clear circuit 310 applying either the high or low voltage to the I/O lines 302 may cause the storage capacitor 324 to store a value that is based on the voltage applied to the I/O lines 302 by the clear circuit 310. That is, the clear circuit 310 may overwrite the data previously stored by a storage capacitor 324 with a value that is based on the voltage applied to the I/O lines 302 by the clear circuit 310. For example, if the clear circuit 310 applies a low voltage (e.g., a ground voltage) to the I/O lines 302, the corresponding storage capacitors 324 may be overwritten to store a logic value “0.” Additionally, if the clear circuit 310 applies a high voltage (e.g., V_{CC}) to the I/O lines 302, the corresponding storage capacitors 324 may be overwritten to store a logic value “1.”

The clear circuit 310 may be configured to drive the I/O lines 302 to the high or low voltage directionally. That is, the clear circuit 310 may drive the I/O lines 302 to the high or low voltage in the direction of the digit lines 308 (e.g., toward the digit lines 308) without driving the I/O lines 302 to the high or low voltage in the direction of the data buffer (e.g., away from the digit lines 308). To drive the I/O lines directionally, the clear circuit 310 may also be configured to isolate the applied voltage directionally. Accordingly, if the clear enable line 312 activates the clear circuit 310-a and the clear circuit 310-b after a read operation associated with either the storage capacitor 324-a or the storage capacitor 324-b, the clear circuit 310-a and the clear circuit 310-b may not overwrite the data on the I/O lines 302-a or the I/O lines 302-b in the direction of the data buffer.

In some cases, a column decoder (such as the column decoder 212) may identify the column address associated with the access operation and apply a voltage (e.g., a high voltage, such as V_{CC}) to the clear enable line 312 that is associated with the identified column address. Accordingly, the clear circuit 310 (or a plurality of clear circuits 310) may be activated based on the column address associated with the access operation. In some cases, the clear enable line 312 applying a voltage to one or more clear circuits 310 may cause the one or more clear circuits 310 to overwrite the data stored in the subset of memory cells that are associated with the column address (e.g., and the row address associated with the access operation). Accordingly, the one or more clear circuits 310 may apply either a high voltage or a low voltage to the I/O lines 302, which may cause each memory cell in the subset of memory cells to store a uniform value (e.g., a logic value “0” if the one or more clear circuits 310 apply a low voltage to the I/O lines 302, a logic value “1” if the one or more clear circuits 310 apply a high voltage to the I/O lines 302).

The clear enable line 312 may apply a voltage to the clear circuits 310 based on an access command indicating for the memory device to clear or overwrite the data after performing the read operation. In one example, the access command may correspond to a read command that indicates for the memory device to perform a read operation and to overwrite the data stored by the subset of memory cells after performing the read operation. In another example, the access command may correspond to an overwrite command that is issued or generated independently of a read command (e.g., that is associated with a distinct command sequence from a read command sequence).

In another example, the memory device may determine to overwrite the data stored by the subset of memory cells based on an address associated with the read operation. For example, the memory device may be configured to automatically overwrite data stored by memory cells that are associated with a predefined address space. In some cases, the predefined address space may correspond to a portion of a memory array that is configured to store sensitive information. Here, the memory device may determine whether to clear (e.g., to overwrite) data from a subset of memory cells after performing a read operation based on the address indicated by the read command. If the address indicated by the read command is within the predefined address space, the memory device may overwrite the data stored in the subset of memory cells after outputting the data from the subset of memory cells. Additionally, if the address indicated by the read command is not within the predefined address space, the memory device may refrain from overwriting the data stored in the subset of memory cells after outputting the data from the subset of memory cells.

In some cases, a portion of the memory array may include clear circuits 310 and another portion of the memory array may not include clear circuits 310. A portion of the memory array may correspond to one or more banks within the memory array, one or more bank groups within the memory array, a row address space within a bank of the memory array, or another division of the address space within the memory array. Here, there may be portions of the memory array that are not configured to overwrite data after outputting the data (e.g., based on not including clear circuits 310). In some cases, the memory device may be configured to store sensitive data within portions of the memory array that include the clear circuits 310. Accordingly, the sensitive data may be associated with additional protection (e.g., by overwriting the sensitive data after outputting the sensitive data) as compared to other data (e.g., that is not sensitive) and stored in portions of the memory array that do not include the clear circuits 310. In some cases, selectively including the clear circuits 310 based on whether the portion of the memory array is configured to store sensitive data may decrease a footprint associated with the clear circuits 310 (e.g., as compared to a memory array that includes clear circuits 310 throughout the memory array) while still ensuring that sensitive data is associated with an increased security and integrity.

As indicated above, FIG. 3 is provided as an example. Other examples may differ from what is described with regard to FIG. 3.

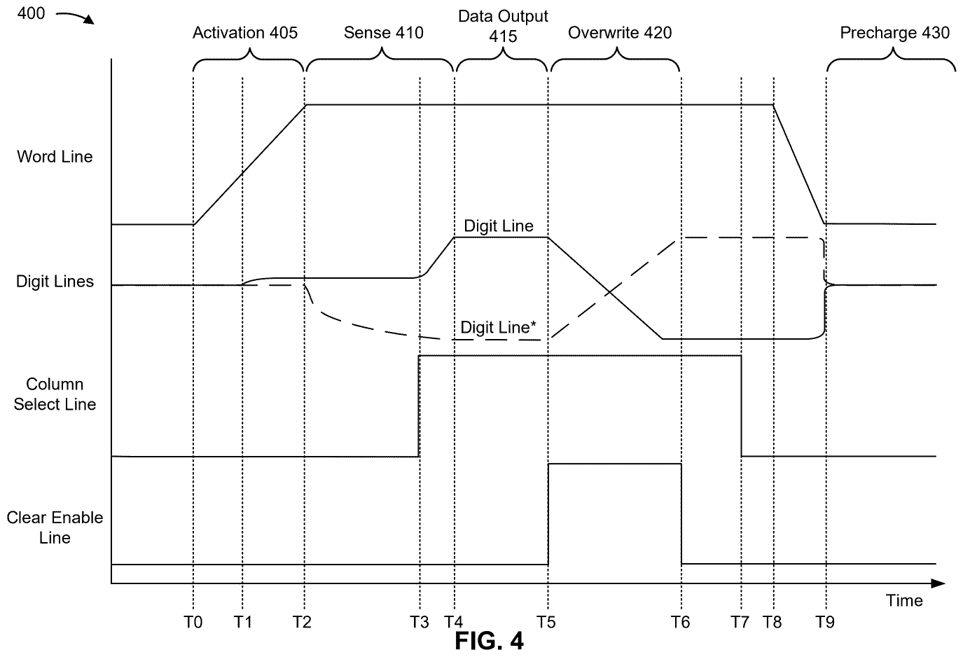

FIG. 4 is a timing diagram 400 associated with overwriting data. The operations described in connection with FIG. 4 may be performed by the memory system 110 and/or one or more components of the memory system 110, such as the memory system controller 115, one or more memory devices 120, and/or one or more local controllers 125. Additionally, the operations described in connection with FIG. 4 may be performed by the memory device 200 or the circuitry 300 and/or one or more components of the memory device or the circuitry 300.

The timing diagram 400 illustrates the voltages across a word line (such as an access line 206 or a word line 306), a digit line (such as a digit line 308) and a complementary digit line (e.g., digit line*), a column select line (such as a column select line 314), and a clear enable line (such as a clear enable line 312). The timing diagram 400 may illustrate operations associated with a read operation and overwriting data after the read operation.

The timing diagram 400 illustrates an activation 405 at time T0, associated with performing a read operation. In some cases, a memory device may perform the activation 405 based on initiating the read operation. During an activation 405, the row address associated with the read operation is decoded, the corresponding word line is activated, and the charges from the set of storage capacitors associated with the activated word line are transferred to corresponding digit lines. In particular, at time T0, a voltage may be applied to the word line. For example, the word line may be driven from a low voltage (e.g., a ground voltage) to a high voltage (e.g., V_{CC}). At time T1, the charge from a memory cell may be transferred from a storage capacitor to the digit line (e.g., based on the word line being activated). In the example timing diagram 400, the charge may correspond to a logic value “1.” Accordingly, at time T1, the voltage of the digit line may increase slightly (e.g., from a precharge voltage, such as V_{CC}/2) based on the charge from the storage capacitor being transferred to the digit line.

Following the activation 405, at 410 the memory device may sense the logic values stored by the set of storage capacitors. In particular, at time T2, the sense amplifiers may be activated, and may pull the digit line and the complementary digit line (e.g., the digit line*) to the rails (e.g., to either a ground voltage or a high voltage). That is, the sense amplifier may amplify the difference between the voltage of the digit line and the digit line*, and pull the digit line to a high rail (Vcc) and the digit line* to the low rail (e.g., ground).

At time T3, the column select line may be activated. For example, the column address associated with the read operation is decoded, and the corresponding column select line is activated. That is, a high voltage (e.g., V_{CC}) may be applied to the column select line, which may couple a subset of the sense amplifiers to I/O lines. The time between time T4 and time T5 may correspond to a data output 415. In particular, at time T4, the data represented by the digit line voltage may be transferred to the I/O lines based on the column select line being activated.

At time T5, the clear enable line may be activated, which may cause the overwrite 420. For example, the column address associated with the read operation is decoded, the corresponding clear enable line is activated. That is, a high voltage (e.g., V_{CC}) may be applied to the clear enable line, which may activate the clear circuit. Then, the clear circuit may apply a voltage (e.g., a ground voltage) to the I/O lines, which may be coupled to the digit line. Accordingly, at time T5 and based on the clear circuit driving the I/O lines to a ground voltage, the voltage of the digit line may also be driven to the ground voltage. In some cases, the voltage of the digit line, at time T5, may be driven to a same voltage that is applied to the I/O lines by the clear circuit. Additionally, at time T5, the voltage of the digit line* may be driven to a complementary high voltage (e.g., to V_{CC}). Based on the voltage of the digit line being driven to ground and the word line still being activated at time T5, a uniform value (e.g., corresponding to the voltage applied to the digit line) may be stored in the memory cell. In the timing diagram 400, the uniform value may correspond to a logic value “0.”

At time T6, the clear enable line may be deactivated. That is, the high voltage may be removed from the clear enable line, and the clear enable line voltage may decrease to a ground voltage. Deactivating the clear enable line may in turn deactivate the clear circuit(s).

At time T7, the column select line may be deactivated. That is, the high voltage may be removed from the column select line, and the column select line voltage may decrease to a ground voltage. Deactivating the column select line may isolate the sense amplifiers, digit lines, and memory cells (e.g., the storage capacitors) from the I/O lines.

At time T8, the word line may be deactivated. That is, the high voltage may be removed from the word line, and the word line voltage may decrease to a ground voltage. Deactivating the word line may isolate the memory cells (e.g., the storage capacitors) from the sense amplifiers. After time T9, at 430 the memory device may precharge the digit line and the digit line*. For example, the memory device may apply a reference voltage (e.g., V_{CC}/2) to the digit line and the digit line*.

As indicated above, FIG. 4 is provided as an example. Other examples may differ from what is described with regard to FIG. 4.

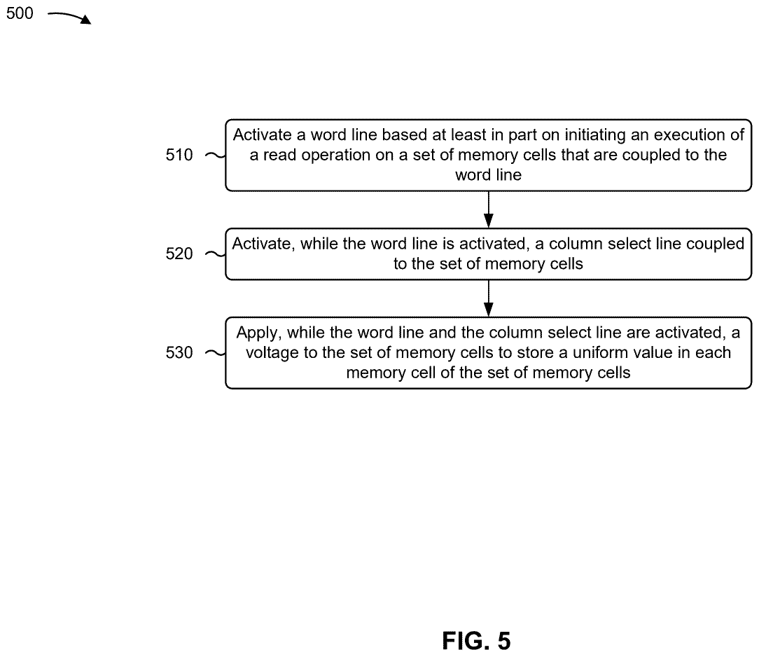

FIG. 5 is a flowchart of an example method 500 associated with overwriting data. In some implementations, a memory device (e.g., the memory device 120) may perform or may be configured to perform the method 500. In some implementations, another device or a group of devices separate from or including the memory device (e.g., the system 100) may perform or may be configured to perform the method 500. Additionally, or alternatively, one or more components of the memory device (e.g., the memory system controller 115, the local controller 125, the memory controller 214, the row decoder 210, the sense component 216, the column decoder 212, the clear circuit 310, the I/O driver 304, or the sense amplifier 316) may perform or may be configured to perform the method 500. Thus, means for performing the method 500 may include the memory device and/or one or more components of the memory device. Additionally, or alternatively, a non-transitory computer-readable medium may store one or more instructions that, when executed by the memory device (e.g., the local controller 125 of the memory device 120, the memory controller 214), cause the memory device to perform the method 500.

As shown in FIG. 5, the method 500 may include activating a word line based at least in part on initiating an execution of a read operation on a set of memory cells that are coupled to the word line (block 510). As further shown in FIG. 5, the method 500 may include activating, while the word line is activated, a column select line coupled to the set of memory cells (block 520). As further shown in FIG. 5, the method 500 may include applying, while the word line and the column select line are activated, a voltage to the set of memory cells to store a uniform value in each memory cell of the set of memory cells (block 530).

The method 500 may include additional aspects, such as any single aspect or any combination of aspects described below and/or described in connection with one or more other methods or operations described elsewhere herein.

In a first aspect, applying the voltage to the set of memory cells comprises applying the voltage to a set of I/O lines that are coupled to the set of memory cells via a set of digit lines.

In a second aspect, alone or in combination with the first aspect, applying the voltage to the set of I/O lines comprises applying the voltage to the set of I/O lines in a first direction toward the set of digit lines without applying the voltage to the set of I/O lines in a second direction away from the set of digit lines.

In a third aspect, alone or in combination with one or more of the first and second aspects, the voltage is applied to the set of memory cells until each memory cell of the set of memory cells is storing the uniform value.

In a fourth aspect, alone or in combination with one or more of the first through third aspects, the method 500 includes activating a plurality of sense amplifiers based at least in part on activating the word line, wherein applying the voltage to the set of memory cells occurs while the plurality of sense amplifiers are activated.

In a fifth aspect, alone or in combination with one or more of the first through fourth aspects, the method 500 includes deactivating the word line after applying the voltage to the set of memory cells.

In a sixth aspect, alone or in combination with one or more of the first through fifth aspects, each memory cell of the set of memory cells is storing the uniform value after deactivating the word line.

In a seventh aspect, alone or in combination with one or more of the first through sixth aspects, the method 500 includes deactivating the column select line after applying the voltage to the set of memory cells.

In an eighth aspect, alone or in combination with one or more of the first through seventh aspects, storing the uniform value comprises storing a logic value “0” in each memory cell of the set of memory cells, or storing the uniform value comprises storing a logic value “1” in each memory cell of the set of memory cells.

In a ninth aspect, alone or in combination with one or more of the first through eighth aspects, the method 500 includes receiving a read command indicating a read operation associated with an overwrite operation, wherein the overwrite operation corresponds to storing the uniform value in each memory cell of the set of memory cells after an execution of the read operation.

Although FIG. 5 shows example blocks of a method 500, in some implementations, the method 500 may include additional blocks, fewer blocks, different blocks, or differently arranged blocks than those depicted in FIG. 5. Additionally, or alternatively, two or more of the blocks of the method 500 may be performed in parallel. The method 500 is an example of one method that may be performed by one or more devices described herein. These one or more devices may perform or may be configured to perform one or more other methods based on operations described herein.

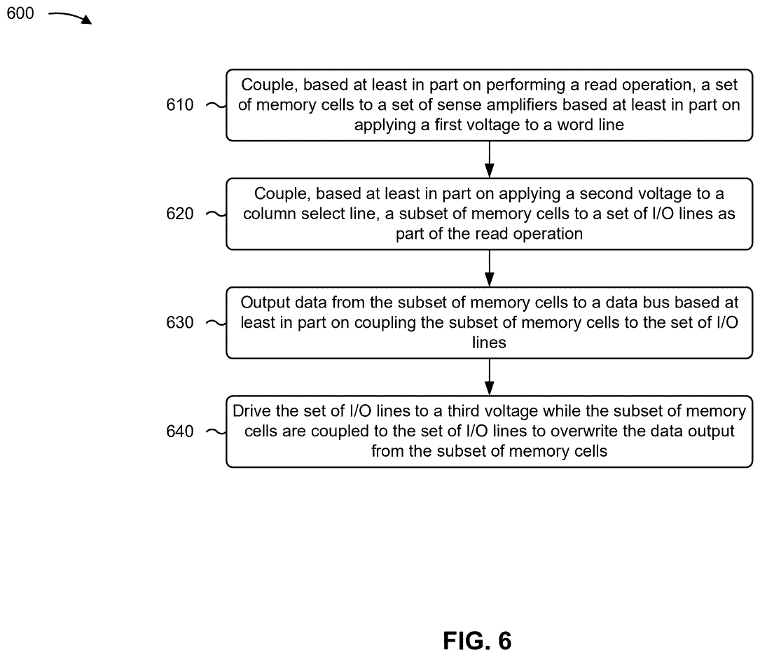

FIG. 6 is a flowchart of an example method 600 associated with overwriting data. In some implementations, a memory device (e.g., the memory device 120) may perform or may be configured to perform the method 600. In some implementations, another device or a group of devices separate from or including the memory device (e.g., the system 100) may perform or may be configured to perform the method 600. Additionally, or alternatively, one or more components of the memory device (e.g., the memory system controller 115, the local controller 125, the memory controller 214, the row decoder 210, the sense component 216, the column decoder 212, the clear circuit 310, the I/O driver 304, or the sense amplifier 316) may perform or may be configured to perform the method 600. Thus, means for performing the method 600 may include the memory device and/or one or more components of the memory device. Additionally, or alternatively, a non-transitory computer-readable medium may store one or more instructions that, when executed by the memory device (e.g., the local controller 125 of the memory device 120, the memory controller 214), cause the memory device to perform the method 600.

As shown in FIG. 6, the method 600 may include coupling, based at least in part on performing a read operation, a set of memory cells to a set of sense amplifiers based at least in part on applying a first voltage to a word line (block 610). As further shown in FIG. 6, the method 600 may include coupling, based at least in part on applying a second voltage to a column select line, a subset of memory cells to a set of I/O lines as part of the read operation (block 620). As further shown in FIG. 6, the method 600 may include outputting data from the subset of memory cells to a data bus based at least in part on coupling the subset of memory cells to the set of I/O lines (block 630). As further shown in FIG. 6, the method 600 may include driving the set of I/O lines to a third voltage while the subset of memory cells are coupled to the set of I/O lines to overwrite the data output from the subset of memory cells (block 640).

The method 600 may include additional aspects, such as any single aspect or any combination of aspects described below and/or described in connection with one or more other methods or operations described elsewhere herein.

In a first aspect, the set of I/O lines are driven to the third voltage while the set of memory cells are coupled to the set of sense amplifiers.

In a second aspect, alone or in combination with the first aspect, driving the set of I/O lines to the third voltage comprises applying the third voltage to the set of I/O lines in a first direction toward the subset of memory cells without applying the third voltage to the set of I/O lines in a second direction away from the subset of memory cells.

In a third aspect, alone or in combination with one or more of the first and second aspects, the method 600 includes isolating, based at least in part on removing the second voltage from the column select line, the subset of memory cells from the set of I/O lines after overwriting the data.

In a fourth aspect, alone or in combination with one or more of the first through third aspects, the method 600 includes isolating, based at least in part on removing the first voltage from the word line, the set of memory cells from the set of sense amplifiers after overwriting the data.

In a fifth aspect, alone or in combination with one or more of the first through fourth aspects, overwriting the data comprises storing a logic value “0” in each memory cell of the subset of memory cells, or storing a logic value “1” in each memory cell of the subset of memory cells.

In a sixth aspect, alone or in combination with one or more of the first through fifth aspects, the method 600 includes activating the set of sense amplifiers coupled to the set of memory cells based at least in part on coupling the set of memory cells to the set of sense amplifiers, wherein driving the set of I/O lines to the third voltage occurs while the set of sense amplifiers are activated.

In a seventh aspect, alone or in combination with one or more of the first through sixth aspects, the set of I/O lines are driven to the third voltage until the data output from the subset of memory cells is overwritten.

In an eighth aspect, alone or in combination with one or more of the first through seventh aspects, the method 600 includes receiving a read command indicating for the memory device to overwrite the data after outputting the data from the subset of memory cells, wherein driving the set of I/O lines to the third voltage is based at least in part on the read command indicating for the memory device to overwrite the data.

Although FIG. 6 shows example blocks of a method 600, in some implementations, the method 600 may include additional blocks, fewer blocks, different blocks, or differently arranged blocks than those depicted in FIG. 6. Additionally, or alternatively, two or more of the blocks of the method 600 may be performed in parallel. The method 600 is an example of one method that may be performed by one or more devices described herein. These one or more devices may perform or may be configured to perform one or more other methods based on operations described herein.

In some implementations, a memory device includes one or more components configured to: couple, based at least in part on performing a read operation, a set of memory cells to a set of sense amplifiers based at least in part on applying a first voltage to a word line; couple, based at least in part on applying a second voltage to a column select line, a subset of memory cells to a set of I/O lines as part of the read operation; output data from the subset of memory cells to a data bus based at least in part on coupling the subset of memory cells to the set of I/O lines; and drive the set of I/O lines to a third voltage while the subset of memory cells are coupled to the set of I/O lines to overwrite the data output from the subset of memory cells.

In some implementations, a method includes activating a word line based at least in part on initiating an execution of a read operation on a set of memory cells that are coupled to the word line; activating, while the word line is activated, a column select line coupled to the set of memory cells; and applying, while the word line and the column select line are activated, a voltage to the set of memory cells to store a uniform value in each memory cell of the set of memory cells.

In some implementations, an apparatus includes means for activating a word line based at least in part on initiating an execution of a read operation on a set of memory cells that are coupled to the word line; means for activating, while the word line is activated, a column select line coupled to the set of memory cells; and means for applying, while the word line and the column select line are activated, a third voltage to the set of memory cells to store a uniform value in each memory cell of the set of memory cells.

In some implementations, a method includes coupling, based at least in part on performing a read operation, a set of memory cells to a set of sense amplifiers based at least in part on applying a first voltage to a word line; coupling, based at least in part on applying a second voltage to a column select line, a subset of memory cells to a set of I/O lines as part of the read operation; outputting data from the subset of memory cells to a data bus based at least in part on coupling the subset of memory cells to the set of I/O lines; and driving the set of I/O lines to a third voltage while the subset of memory cells are coupled to the set of I/O lines to overwrite the data output from the subset of memory cells.

The foregoing disclosure provides illustration and description but is not intended to be exhaustive or to limit the implementations to the precise forms disclosed. Modifications and variations may be made in light of the above disclosure or may be acquired from practice of the implementations described herein.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory device, comprising:
one or more components configured to:
couple, based at least in part on performing a read operation, a set of memory cells to a set of sense amplifiers based at least in part on applying a first voltage to a word line;
couple, based at least in part on applying a second voltage to a column select line, a subset of memory cells to a set of input/output (I/O) lines as part of the read operation;
output data from the subset of memory cells to a data bus based at least in part on coupling the subset of memory cells to the set of I/O lines; and
drive the set of I/O lines to a third voltage while the subset of memory cells are coupled to the set of I/O lines to overwrite the data output from the subset of memory cells.

2. The memory device of claim 1, wherein the set of I/O lines are driven to the third voltage while the set of memory cells are coupled to the set of sense amplifiers.

3. The memory device of claim 1, wherein, to drive the set of I/O lines to the third voltage, the one or more components are configured to:
apply the third voltage to the set of I/O lines in a first direction toward the subset of memory cells without applying the third voltage to the set of I/O lines in a second direction away from the subset of memory cells.

4. The memory device of claim 1, wherein the one or more components are configured to:
isolate, based at least in part on removing the second voltage from the column select line, the subset of memory cells from the set of I/O lines after overwriting the data.

5. The memory device of claim 1, wherein the one or more components are configured to:
isolate, based at least in part on removing the first voltage from the word line, the set of memory cells from the set of sense amplifiers after overwriting the data.

6. The memory device of claim 1, wherein, to overwrite the data, the one or more components are configured to:
store a logic value “0” in each memory cell of the subset of memory cells; or
store a logic value “1” in each memory cell of the subset of memory cells.

7. The memory device of claim 1, wherein the one or more components are configured to:
activate the set of sense amplifiers coupled to the set of memory cells based at least in part on coupling the set of memory cells to the set of sense amplifiers, wherein driving the set of I/O lines to the third voltage occurs while the set of sense amplifiers are activated.

8. The memory device of claim 1, wherein the set of I/O lines are driven to the third voltage until the data output from the subset of memory cells is overwritten.

9. The memory device of claim 1, wherein the one or more components are configured to:
receive a read command indicating for the memory device to overwrite the data after outputting the data from the subset of memory cells, wherein driving the set of I/O lines to the third voltage is based at least in part on the read command indicating for the memory device to overwrite the data.

10. A method, comprising:
activating a word line based at least in part on initiating an execution of a read operation on a set of memory cells that are coupled to the word line;
activating, while the word line is activated, a column select line coupled to the set of memory cells; and
applying, while the word line and the column select line are activated, a voltage to the set of memory cells to store a uniform value in each memory cell of the set of memory cells.

11. The method of claim 10, wherein applying the voltage to the set of memory cells comprises:
applying the voltage to a set of input/output (I/O) lines that are coupled to the set of memory cells via a set of digit lines.

12. The method of claim 11, wherein applying the voltage to the set of I/O lines comprises applying the voltage to the set of I/O lines in a first direction toward the set of digit lines without applying the voltage to the set of I/O lines in a second direction away from the set of digit lines.

13. The method of claim 10, wherein the voltage is applied to the set of memory cells until each memory cell of the set of memory cells is storing the uniform value.

14. The method of claim 10, further comprising:
activating a plurality of sense amplifiers based at least in part on activating the word line, wherein applying the voltage to the set of memory cells occurs while the plurality of sense amplifiers are activated.

15. The method of claim 10, further comprising:
deactivating the word line after applying the voltage to the set of memory cells.

16. The method of claim 15, wherein each memory cell of the set of memory cells is storing the uniform value after deactivating the word line.

17. The method of claim 10, further comprising:
deactivating the column select line after applying the voltage to the set of memory cells.

18. The method of claim 10, wherein:
storing the uniform value comprises storing a logic value “0” in each memory cell of the set of memory cells; or
storing the uniform value comprises storing a logic value “1” in each memory cell of the set of memory cells.

19. The method of claim 10, further comprising:
receiving a read command indicating a read operation associated with an overwrite operation, wherein the overwrite operation corresponds to storing the uniform value in each memory cell of the set of memory cells after an execution of the read operation.

20. An apparatus, comprising:
means for activating a word line based at least in part on initiating an execution of a read operation on a set of memory cells that are coupled to the word line;
means for activating, while the word line is activated, a column select line coupled to the set of memory cells; and
means for applying, while the word line and the column select line are activated, a third voltage to the set of memory cells to store a uniform value in each memory cell of the set of memory cells.

21. The apparatus of claim 20, wherein the means for applying the voltage to the set of memory cells comprise:
means for applying the voltage to a set of input/output (I/O) lines that are coupled to the set of memory cells via a set of digit lines.

22. The apparatus of claim 21, wherein the means for applying the voltage to the set of I/O lines comprise means for applying the voltage to the set of I/O lines in a first direction toward the set of digit lines without applying the voltage to the set of I/O lines in a second direction away from the set of digit lines.

23. The apparatus of claim 20, wherein the voltage is applied to the set of memory cells until each memory cell of the set of memory cells is storing the uniform value.

24. The apparatus of claim 20, further comprising:
means for activating a plurality of sense amplifiers based at least in part on activating the word line, wherein applying the voltage to the set of memory cells occurs while the plurality of sense amplifiers are activated.

25. The apparatus of claim 20, further comprising:
means for deactivating the word line after applying the voltage to the set of memory cells.
